(19) United States
(12) Patent Application Publication
(10) Pub. No.: US 2014/0009876 A1
(43) Pub. Date: Jan. 9, 2014

(54) ELECTRONIC DEVICE AND WIRE FIXING MECHANISM THEREOF

(71) Applicant: AOpen Inc., New Taipei City (TW)

(72) Inventor: Jo-Chiao Wang, New Taipei City (TW)

(21) Appl. No.: 13/935,537

(22) Filed: Jul. 4, 2013

(30) Foreign Application Priority Data
Jul. 9, 2012 (TW) 101124578

(51) Int. Cl. H05K 13/00; H05K 7/02

(52) U.S. Cl. CPC H05K 13/00; H05K 7/02
USPC 361/679.01; 29/729

(57) ABSTRACT

A wire fixing mechanism is provided for fixing a wire to an electronic device. The wire fixing mechanism includes a mechanism body, a wire restriction portion and a fixing portion. The wire restriction portion is connected to the mechanism body, wherein, the wire restriction portion restricts the wire. The fixing portion is connected to the mechanism body, wherein the fixing portion is adapted to be fixed to the electronic device.

### CROSS REFERENCE TO RELATED APPLICATIONS

This Application claims priority of Taiwan Patent Application No. 101124578, filed on Jul. 9, 2012, the entirety of which is incorporated by reference herein.

### BACKGROUND OF THE INVENTION

1. Field of the Invention

The present invention relates to an electronic device, and in particular, relates to an electronic device with a wire fixing mechanism.

2. Description of the Related Art

In standard electronic devices, a power inlet is formed on a housing of the electronic device, and a power line is connected to the power inlet by a tight fitting. However, since the power line is fixed by a tight fitting, the power line is sometimes separated from the electronic device due to an unexpected tug, and if so, the data in the electronic device may be destroyed or the electronic device may be damaged.

Conventionally, a plastic fixing member is utilized to fix the power line to the power inlet by elastic wedging. However, the plastic fixing member deteriorates with time, thus making the power line still susceptible to separation from the electronic device due to unexpected tugs.

### BRIEF SUMMARY OF THE INVENTION

In one embodiment, a wire fixing mechanism is provided for fixing a wire to an electronic device. The wire fixing mechanism includes a mechanism body, a wire restriction portion and a fixing portion. The wire restriction portion is connected to the mechanism body, wherein, the wire restriction portion restricts the wire. The fixing portion is connected to the mechanism body, wherein the fixing portion is adapted to be fixed to the electronic device.

In another embodiment, an electronic device is provided. The electronic device includes an electronic device body, a wire, a fixing member and a wire fixing mechanism. The wire fixing mechanism includes a mechanism body, a wire restriction portion and a fixing portion. The wire restriction portion is connected to the mechanism body, wherein the wire restriction portion restricts the wire. The fixing portion is connected to the mechanism body, wherein the fixing member fixes the fixing portion to the electronic device body.

Utilizing the electronic device and the wire fixing mechanism of an embodiment of the invention, the wire fixing mechanism is fixed to the electronic device body via a screw. Therefore, the fixing effect is improved. Additionally, the wire fixing mechanism restricts the wire, and provides sufficient reacting force to resist external forces.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is an exploded view of the electronic device of an embodiment of the invention;

FIG. 2 is an assembled view of the electronic device of an embodiment of the invention;

FIG. 3 shows a detailed structure of the wire fixing mechanism;

FIG. 4A is a side view of the wire fixing mechanism and the electronic device body of an embodiment of the invention; and

FIG. 4B shows the wire fixing mechanism restricting the wire when the wire is pulled by external forces.

### DETAILED DESCRIPTION OF THE INVENTION

The following description is made for the purpose of illustrating the general principles of the invention and should not be taken in a limiting sense. The scope of the invention is best determined by reference to the appended claims.

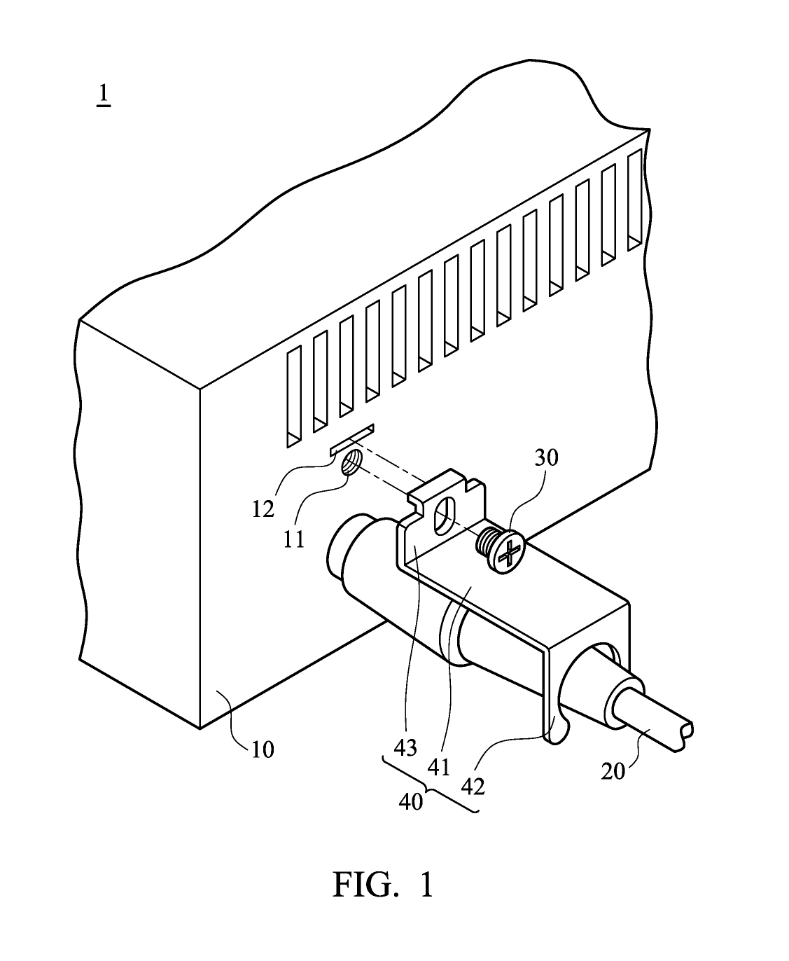

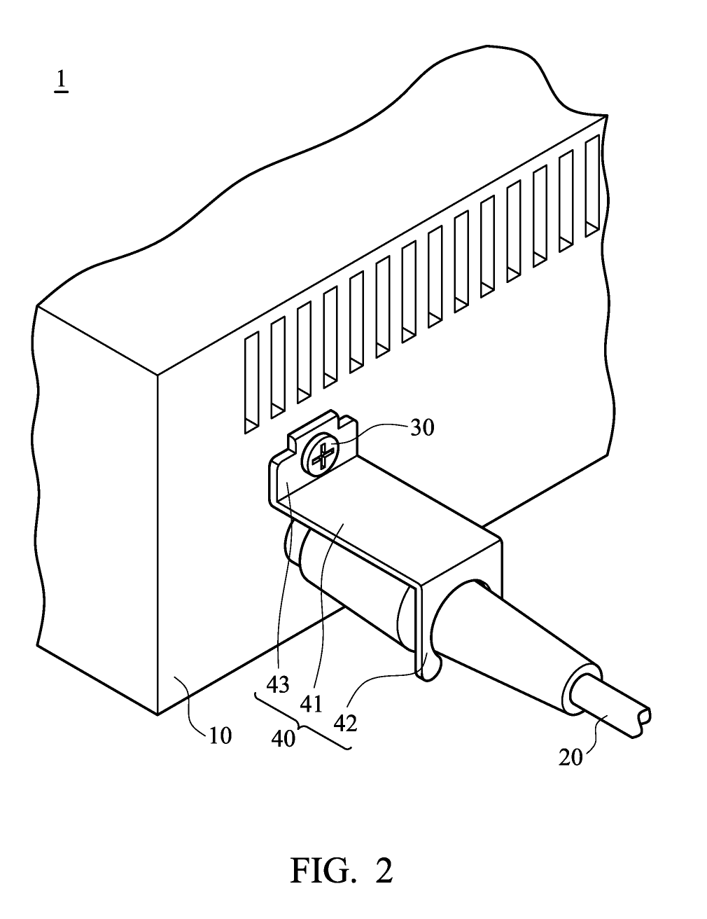

FIG. 1 is an exploded view of a part of the elements of an electronic device of an embodiment of the invention. FIG. 2 is an assembled view of a part of the elements of the electronic device of an embodiment of the invention. With reference to FIGS. 1 and 2, the electronic device 1 of an embodiment of the invention comprises an electronic device body 10, a wire 20, a fixing member 30 and a wire fixing mechanism 40. The wire 20 is plugged to the electronic device body 10. The fixing member 30 fixes the wire fixing mechanism 40 to the electronic device body 10. The wire fixing mechanism 40 restricts the wire 20 to limit the position of the wire 20 relative to the electronic device body 10.

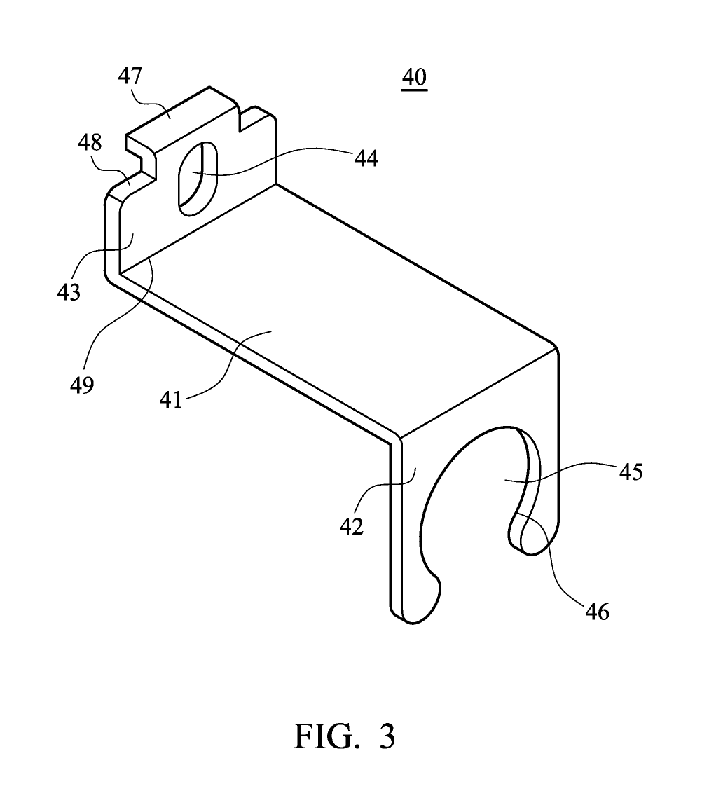

FIG. 3 shows a detailed structure of the wire fixing mechanism 40, wherein the wire fixing mechanism 40 comprises a mechanism body 41, a wire restriction portion 42, and a fixing portion 43. The wire restriction portion 42 is connected to the mechanism body 41. The wire restriction portion 42 restricts the wire 20. The fixing portion 43 is connected to the mechanism body 41, wherein the fixing member 30 fixes the fixing portion 43 to the electronic device body 10.

With reference to FIG. 3, an opening 44 is formed on the fixing portion 43, and the fixing member 30 passes through the opening 44 to fix the fixing portion 43 to the electronic device body 10. In this embodiment, the opening 44 is longitudinal. The fixing member 30 can be screw. In one embodiment, the opening 44 can also be a notch. For example, the opening 44 can be a downward notch allowing the wire fixing mechanism 40 to separate from the wire 20 when the fixing member 30 is loose but not separated from the electronic device body 10.

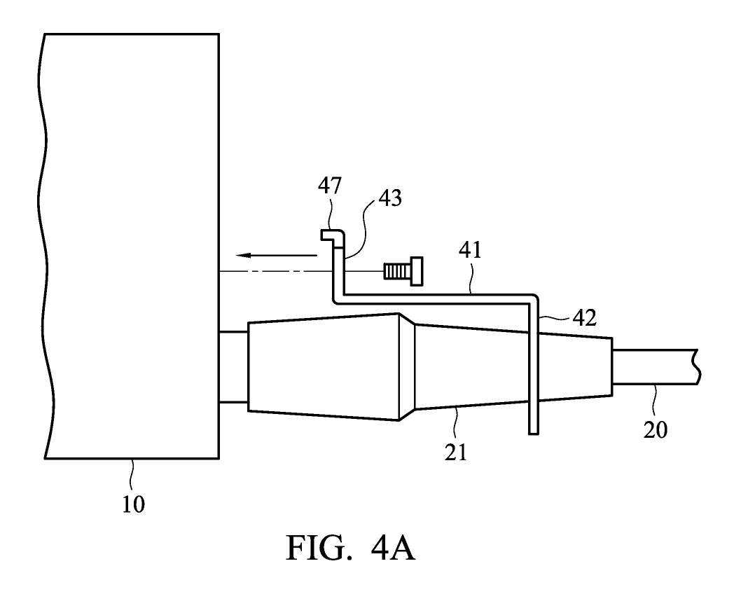

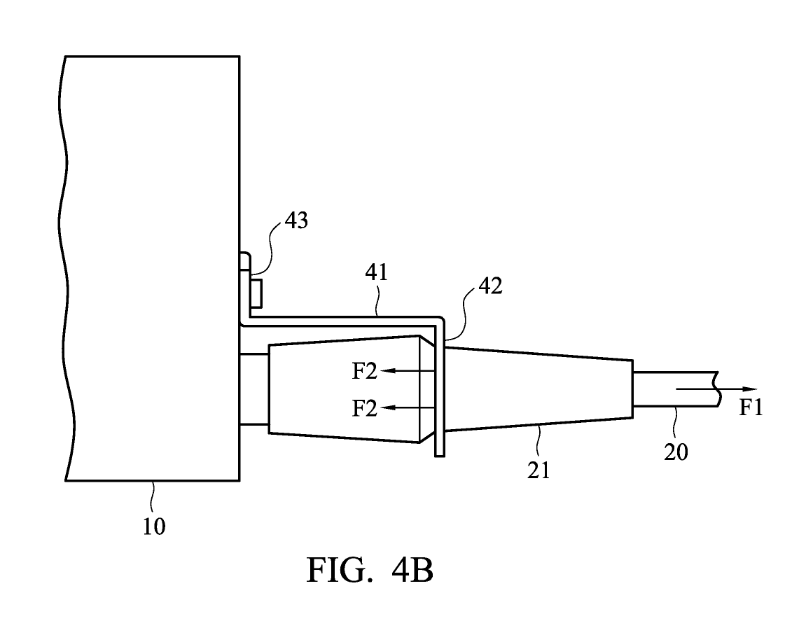

With reference to FIG. 3, a restriction notch 45 is formed on the wire restriction portion 42, and the wire 20 passes through the restriction notch 45. The restriction notch 45 is circular. An edge 46 of the restriction notch 45 abuts the wire 20. With reference to FIGS. 4A and 4B, in this embodiment, the wire 20 comprises a cone-shaped portion 21. The cone-shaped portion 21 abuts the edge 46 of the restriction notch 45. With reference to FIG. 4B, when an external force F1 is applied to the wire 20, the wire restriction portion 42 provides a reacting force F2 to the cone-shaped portion 21 to prevent the wire 20 from separated from the electronic device body 10 due to the external force F1.

With reference to FIG. 3, in this embodiment, the wire fixing mechanism 40 is made of metal, for example, stainless steel. The wire restriction portion 42 and the fixing portion 43 are integrally formed with the mechanism body 41. In this embodiment, the wire restriction portion 42 extends perpendicular to the mechanism body 41, and the fixing portion 43 extends perpendicular to the mechanism body 41.

With reference to FIG. 3, the wire fixing mechanism 40 further comprises at least one positioning portion 47, wherein the positioning portion 47 is formed on a first side 48 of the fixing portion 43, and a second side 49 of the fixing portion 43 is connected to the mechanism body 41, and the first side 48 is opposite to the second side 49. In this embodiment, a cross-section of the positioning portion 47 is L-shaped.

With reference to FIG. 1, a fixing hole 11 and a positioning structure 12 are formed on the electronic device body 10. The positioning structure 12 is near to the fixing hole 11. In this embodiment, the positioning structure 12 is a hole. The positioning portion 47 extends into and abuts the positioning structure 12 to position the wire fixing mechanism 40 during the fixing process. The fixing member 30 passes through the fixing portion 43 to be fixed into the fixing hole 11 to fix the wire fixing mechanism 40 to the electronic device body 10.

In this embodiment, the positioning structure 12 is a hole. However, the invention is not limited thereto. In other embodiments, the positioning structure 12 can be a protrusion or other structures which matches the positioning portion 47.

The wire 20 can be a power line or other transmission lines.

Utilizing the electronic device and the wire fixing mechanism of the embodiment of the invention, the wire fixing mechanism is fixed to the electronic device body via a screw. Therefore, the fixing effect is improved. Additionally, the wire fixing mechanism restricts the wire, and provides sufficient reacting force to resist external forces.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A wire fixing mechanism, for fixing a wire to an electronic device, comprising:
a mechanism body;
a wire restriction portion, connected to the mechanism body, wherein, the wire restriction portion restricts the wire; and
a fixing portion, connected to the mechanism body, wherein the fixing portion is adapted to be fixed to the electronic device.

2. The wire fixing mechanism as claimed in claim 1, wherein an opening is formed on the fixing portion.

3. The wire fixing mechanism as claimed in claim 2, wherein a fixing member passes through the opening to fix the fixing portion to the electronic device.

4. The wire fixing mechanism as claimed in claim 2, wherein the opening is longitudinal.

5. The wire fixing mechanism as claimed in claim 2, wherein the opening is a downward notch.

6. The wire fixing mechanism as claimed in claim 1, wherein a restriction notch is formed on the wire restriction portion, and the wire passes through the restriction notch, and an edge of the restriction notch abuts the wire.

7. The wire fixing mechanism as claimed in claim 6, wherein the restriction notch is circular.

8. The wire fixing mechanism as claimed in claim 1, wherein the wire fixing mechanism is made of metal, and the wire restriction portion and the fixing portion are integrally formed with the mechanism body, and the wire restriction portion extends perpendicular to the mechanism body, and the fixing portion extends perpendicular to the mechanism body.

9. The wire fixing mechanism as claimed in claim 1, further comprising at least one positioning portion, wherein the positioning portion is formed on a first side of the fixing portion, and a second side of the fixing portion is connected to the mechanism body, and the first side is opposite to the second side.

10. The wire fixing mechanism as claimed in claim 9, wherein a cross-section of the positioning portion is L-shaped.

11. An electronic device, comprising:
an electronic device body;
a wire;
a fixing member; and
a wire fixing mechanism, comprising:
a mechanism body;
a wire restriction portion, connected to the mechanism body, wherein the wire restriction portion restricts the wire; and
a fixing portion, connected to the mechanism body, wherein the fixing member fixes the fixing portion to the electronic device body.

12. The electronic device as claimed in claim 11, wherein an opening is formed on the fixing portion, and the fixing member passes through the opening to fix the fixing portion to the electronic device body.

13. The electronic device as claimed in claim 12, wherein the opening is longitudinal.

14. The electronic device as claimed in claim 12, wherein the opening is a downward notch.

15. The electronic device as claimed in claim 11, wherein a restriction notch is formed on the wire restriction portion, and the wire passes through the restriction notch, and an edge of the restriction notch abuts the wire.

16. The electronic device as claimed in claim 15, wherein the restriction notch is circular, and the wire comprises a cone-shaped portion, and the cone-shaped portion abuts the restriction notch.

17. The electronic device as claimed in claim 11, wherein the wire fixing mechanism is made of metal, and the wire restriction portion and the fixing portion are integrally formed with the mechanism body, and the wire restriction portion extends perpendicular to the mechanism body, and the fixing portion extends perpendicular to the mechanism body.

18. The electronic device as claimed in claim 11, wherein the fixing mechanism further comprises at least one positioning portion, wherein the positioning portion is formed on a first side of the fixing portion, and a second side of the fixing portion is connected to the mechanism body, and the first side is opposite to the second side, and a fixing hole and a positioning structure are formed on the electronic device body, and the positioning structure is near to the fixing hole, and the positioning portion abuts the positioning structure, and the fixing member is fixed in the fixing hole to fix the fixing portion to the electronic device body.

19. The electronic device as claimed in claim 18, wherein a cross-section of the positioning portion is L-shaped.
